(19) United States
(12) Patent Application Publication
(10) Pub. No.: US 2012/0114978 A1
(43) Pub. Date: May 10, 2012

(54) Energy Storage Module

(76) Inventor: Claude Beauregard, JR., Canton, MI (US)

(21) Appl. No.: 12/943,929

(22) Filed: Nov. 10, 2010

(51) Int. Cl. H05K 1/16; H01M 10/42; H01G 9/00

(52) U.S. Cl. 429/7; 174/252; 361/500

(57) ABSTRACT

This invention comprise an energy storage module consisting of surface mounted solid state energy cells attached to a rigid circuit board with tabbed ends that act as positive and negative electrodes. The solid state energy cells are attached to each other by use of surface connection links on the rigid circuit board. The rigid circuit board is then inserted into a battery can with interior connection points that can accommodate the insertion of a tabbed end of the rigid circuit board so that positive voltage can be directed out to one external terminal end of the battery can and negative voltage can be directed out to another external terminal of the battery can.

### REFERENCES SITED

U.S. patent Documents

| | | |
|---|---|---|
| Cheiky | 4,913,983 | Metal-Air Battery Power Supply |
| Waters et al. | 5,639,571 | Battery Pack |
| Schoultz | 5,942,353 | Battery with Replaceable Cells |
| Clarke et al. | 7,625,663 | Cerium batteries |
| Lafleur et al. | 7,626,363 | Lithium battery pack management |
| | | and system therefore |
| Jeon et al. | 7,625,665 | Secondary battery module and end- |
| | | plate used in the same |
| Wilk et al. | 7,630,181 | High-Power Ultracapacitor Energy |
| | | Storage Pack and Method of Use |
| Wilk et al. | 7,218,489 | High-Power Ultracapacitor Energy |
| | | Storage Pack and Method of Use |
| Wilk et al. | 7,085,112 | High-Power Ultracapacitor Energy |
| | | Storage Pack and Method of Use |
| Jaggar | 3,875,479 | Electrical Apparatus |
| Jordan et al. | 3,983,458 | Electrical Device Assembly and Method |
| Sprando | 4,021,631 | Electrical Header Device |
| Black | 4,314,008 | Thermoelectric Temperature stabilized |
| | | Battery System |
| Patsiokas et al | 5,020,136 | Battery Pack Antenna Suitable for use |
| | | with Two-way Portable Transceivers |
| Waters et al | 5,639,571 | Battery Pack |
| Mitra et al | 5,707,242 | System and Connector for the Electrical |
| | | Interconnection of Component Boards |
| Oda et al | 6,445,582 | Power Supply Apparatus |
| Bando et all | 2004/0043287 | Battery-Type Power Supply Unit |
| Kim | 2005/0250006 | Secondary Battery Module |

### FIELD OF INVENTION

The field of invention relates to an energy storage device composed of a circuit board with a number of solid state devices connected to store voltage and a micro voltage regulator as needed to regulate voltage output from the energy storage module.

### BACKGROUND OF THE INVENTION

The concept of providing a means to provide and store electricity using portable storage devices such as batteries and capacitors as been around for awhile and the connection of individual batteries in series to provide increased energy is well known. Batteries are limited by the chemical reaction that occurs in the battery to produce electricity. This same chemical reaction also limits the rate at which they can be recharged. Rechargeable batteries are charged by some external means in order to maintain their useful lifetime. The ability to retain voltage degrades over the useful lifetime of both depending upon the length of their use as well as the manufacturing process used in their creation. This includes lithium ion types. Capacitors can also be connected in series and bundled in packs to provide energy however they can't generally store as much energy as a battery of equal size and are more expensive. Additionally capacitors operate efficiently in a narrow temperature range and voltage leakage and unexpected discharge is a common problem. When these singular batteries or capacitors are used in the form of a battery pack, capacitor pack, or energy cell pack each will become imbalanced with one or more of the devices that make up the pack faltering before the others reducing the useful lifetime of the energy pack. Once the pack lifetime has been depleted it must be deposed of.

Another issue faced by these types of systems is their disposal. The chemical substances used in batteries are toxic and do not break down in the environment. For that reason they must be disposed of using special means that will prevent the chemicals from leaching out of the casing and into water supplies. These batteries also pose a potential fire hazard if overcharged as in the case of Lithium ion batteries.

Solid state components are scalable but you need a storage system design that can incorporate them for long term storage of voltage both primary and secondary.

Currently many if not all energy storage modules or battery packs are comprised of batteries such as AA or AAA alkaline cells, lithium thionyl chloride, lithium coin cells, etc. Each type of battery used for these packs has chemistry unique to the purpose for which the pack will be used. Some battery packs will perform well at higher temperature; some offer high energy density, while others are designed for prolonged periods of steady state current drain. Yet all batteries have inherent limitations with respect to operating life, ability to deliver high pulse currents.

Another factor that remains constant is the overall weight of the pack itself. Although circuit and device miniaturization as moved forward the bulky nature of battery packs remains a constant. The burden of these weighty packs has additional cost associated with them in terms of overall device design and weight restrictions that could be solved. Battery packs in a variety of different configurations are used in toys, electric vehicles and a host of other products that require electricity in order to operate.

### BRIEF SUMMARY OF THE INVENTION

It is an object of the present invention to provide an energy storage module that uses a series of solid state energy components placed on a rigid circuit board. The board depending on the configuration of the energy storage module is housed inside a battery can with a means that can used to discharge the stored energy in the energy storage device. The use of solid state components or other energy cell component reduces the chemical waste associated with the disposal of toxic chemicals that are common with other energy storage devices and their associated casing. The use of solid state energy components also reduces drastically the weight footprint of the energy storage pack. This represents an improvement over previous single battery types and battery packs.

### BRIEF DESCRIPTION OF DRAWINGS

In this preferred embodiment:

FIG. 1 is a front view of the rigid circuit board for the AA form factor storage module.

FIG. 2 is a perspective view of the rigid circuit board for the AA form factor storage module.

FIG. 3 is a cut away view of the rigid circuit board for the AA form factor storage module inside an AA battery can.

FIG. 4 is a cut away perspective view of the rigid circuit board for the AA form factor storage module inside an AA battery can.

FIG. 5 is a bottom view of the rigid circuit board for the AA form factor storage module inside the AA battery can.

FIG. 6 is a top view of the rigid circuit board for the AA form factor storage module inside the AA battery can.

FIG. 7 is top view of the rigid circuit board for the cell phone form factor storage module.

FIG. 8 is bottom view of the rigid circuit board for the cell phone form factor storage module.

### DETAILED DESCRIPTION OF INVENTION

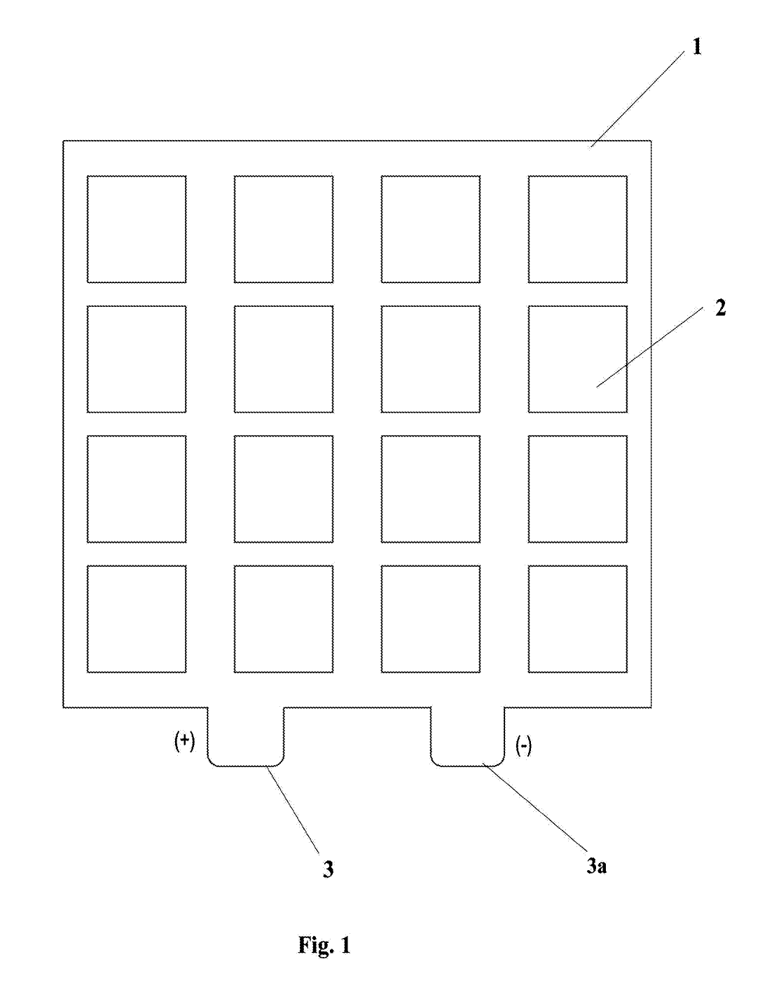

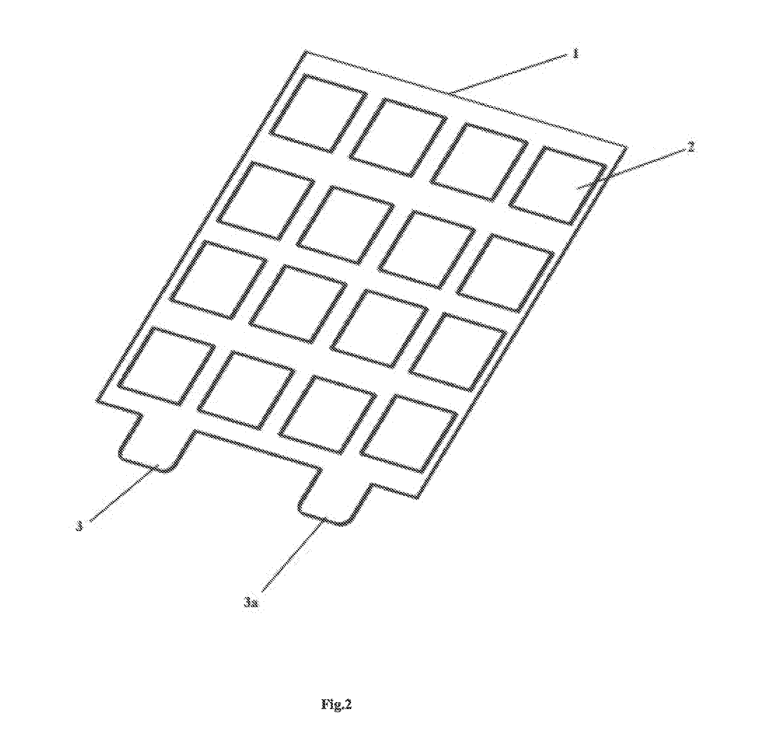

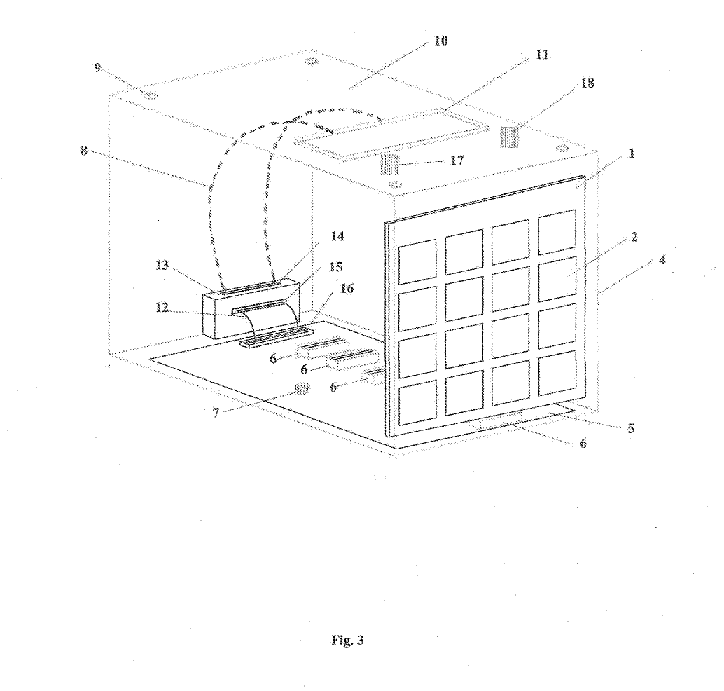

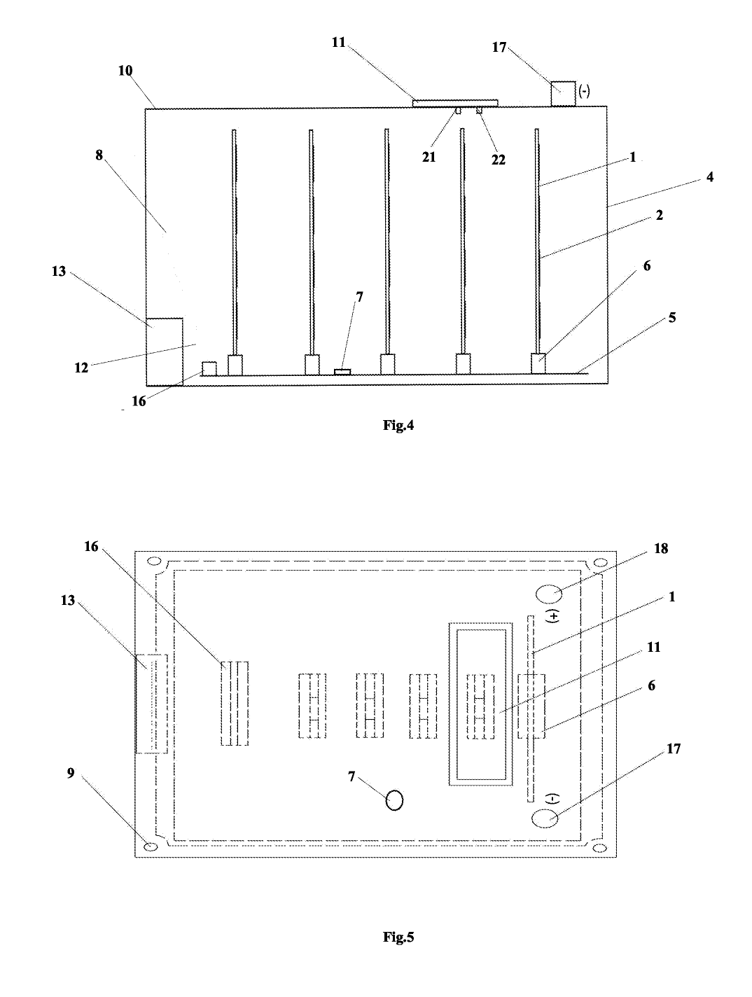

As shown in FIG. 1 the rigid AA form factor circuit board (1) is comprised of surface mounted solid state energy cell (3a) and surface mounted solid state energy cell (3b), which are attached to the rigid AA form factor circuit board (1) by appropriate means. The rigid AA form factor circuit board (1) has a male output tab (2a) at one end and a male output tab (2b) at one end. Positive connection point (15c) of surface mounted solid state energy cell (3a) is connected to positive connection point (15d) of surface mounted solid state energy cell (3b) using connection link (4b). Negative connection point (15h) of surface mounted solid state energy cell (3a) is connected to negative connection point (15g) of surface mounted solid state energy cell (3b) using connection link (4d). Positive voltage from solid state energy cell (3a) is directed out from contact point (15b) using connection link (4a), which is also connected to contact point (15a) of male output tab (2a). Negative voltage from solid state energy cell (3b) is directed out from contact point (15f) using connection link (4c), which is also connected to contact point (15e) of male output tab (2b). FIG. 2 shows a perspective view of the same.

FIG. 3 shows a cut away view of the AA battery can (5) or appropriate container with the rigid AA form factor circuit board (1) fitted inside. The rigid AA form factor circuit board (1) is held in place by sliding the rigid AA form factor circuit board (1) through side retaining slot (7a) and side retaining slot (7b). Output tab (2b) inserts into female receptacle (6b) and output tab (2a) inserts into female receptacle (6a) as the battery can (5) is sealed. Positive voltage output is then directed to positive external end point (8) as shown in FIG. 3, FIG. 4 and FIG. 5 while negative voltage is directed to negative external end (9) as shown in the FIG. 6. FIG. 4 shows a perspective view the AA battery can (5) with the rigid AA form factor circuit board (1) fitted inside.

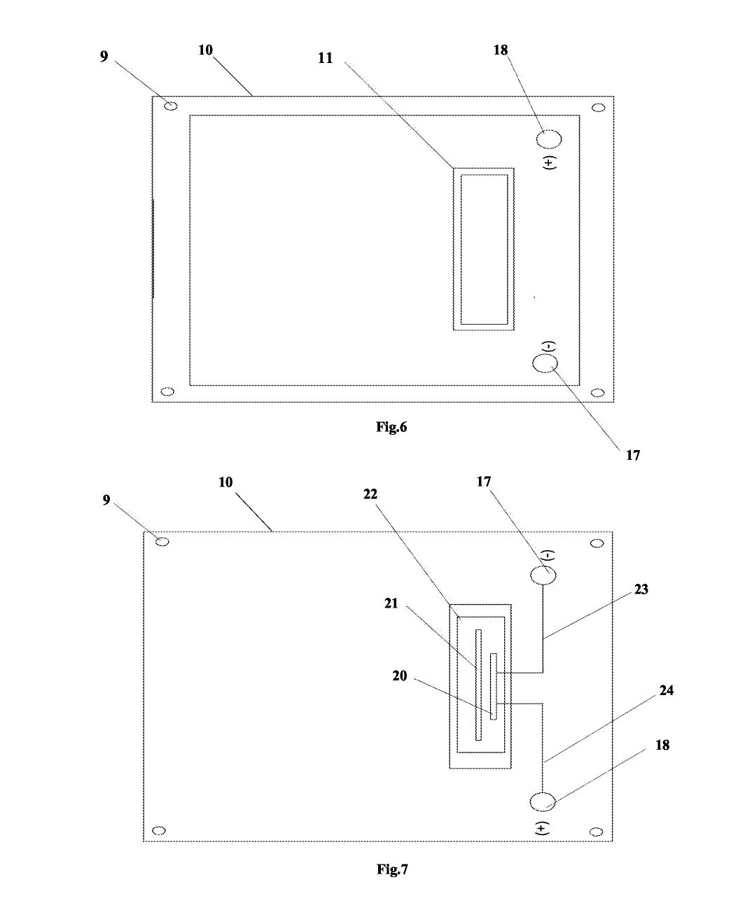

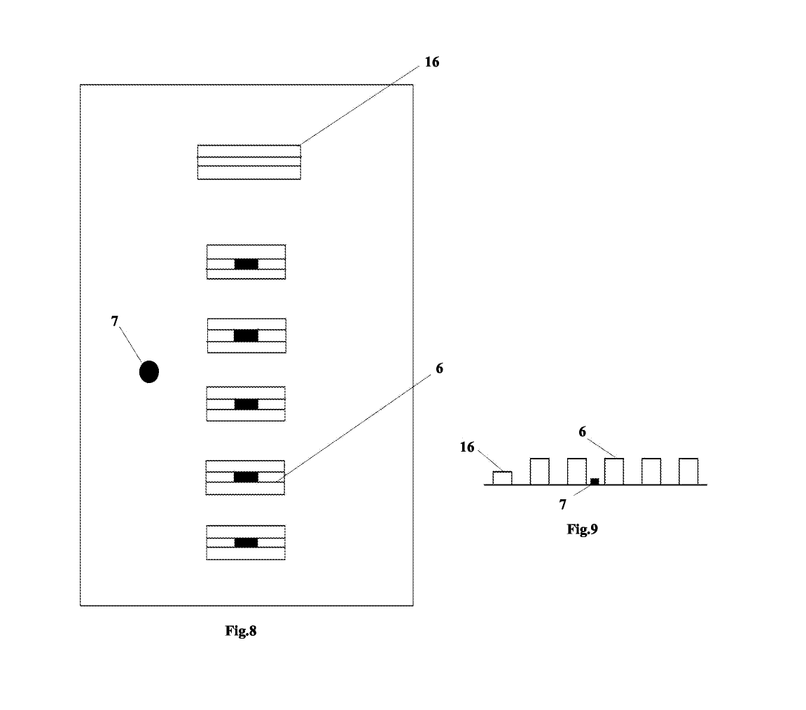

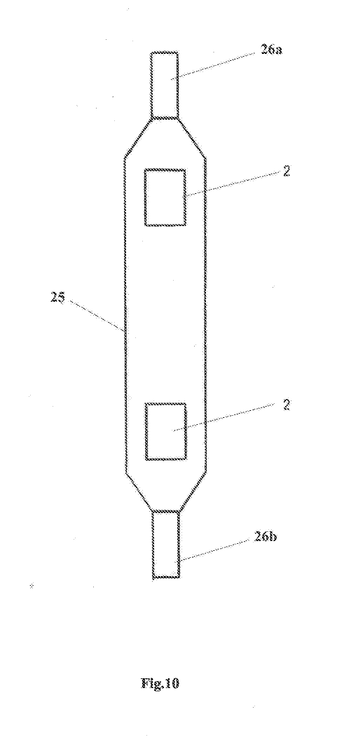

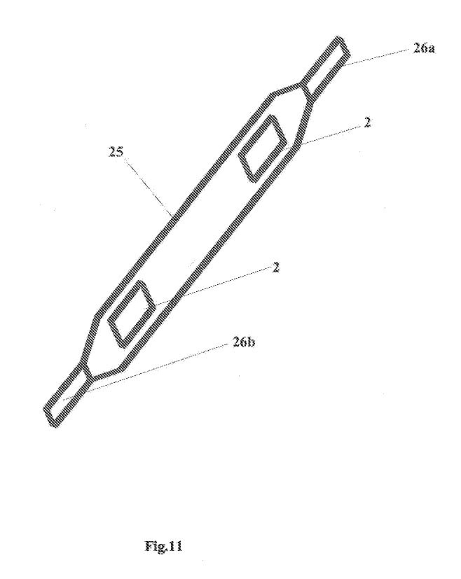

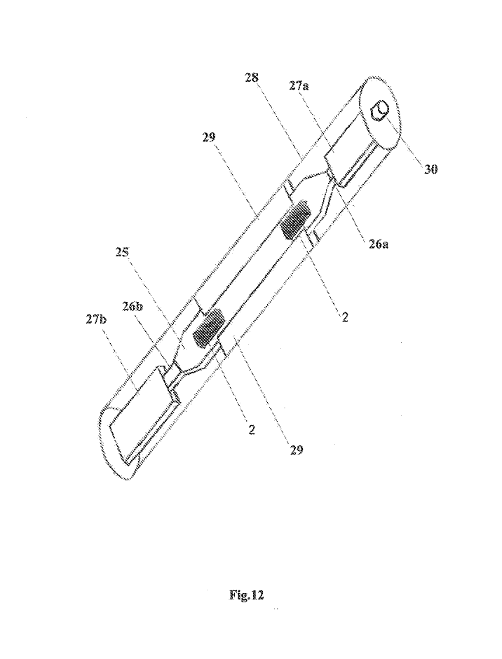

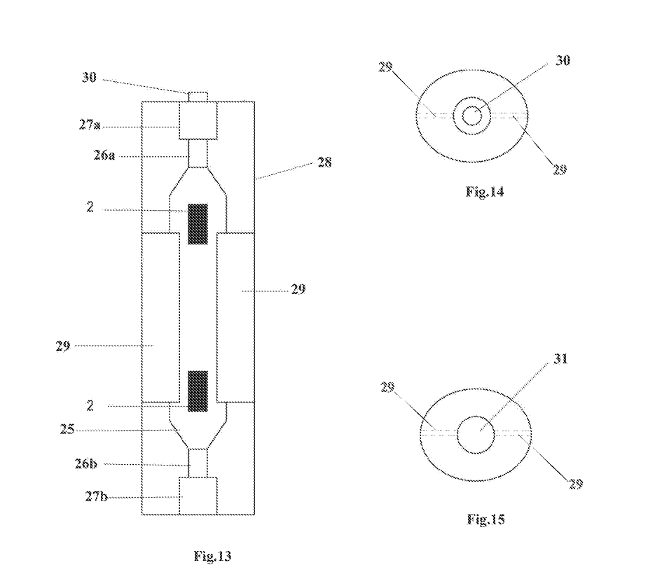

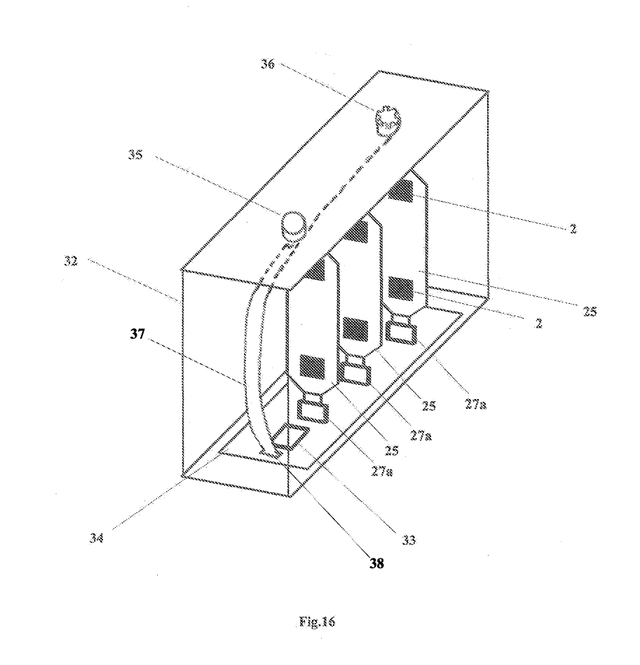

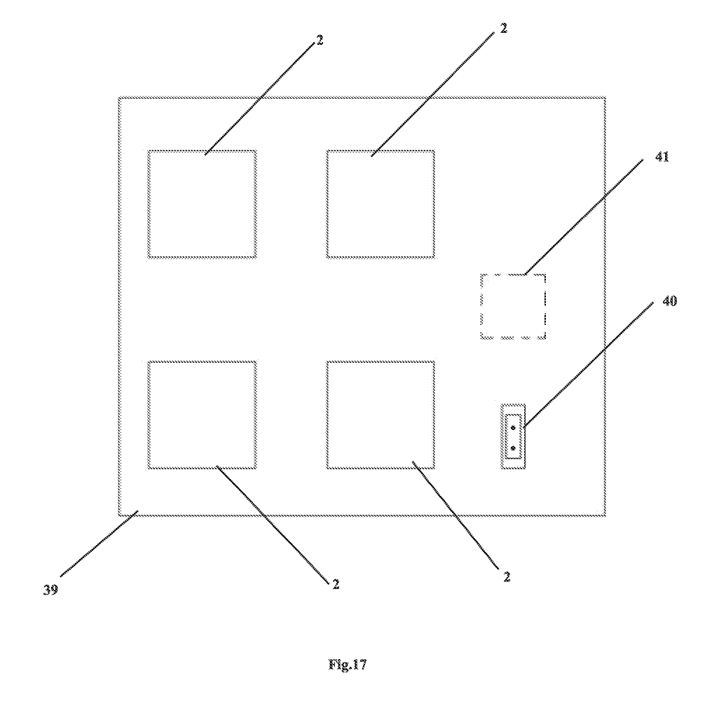

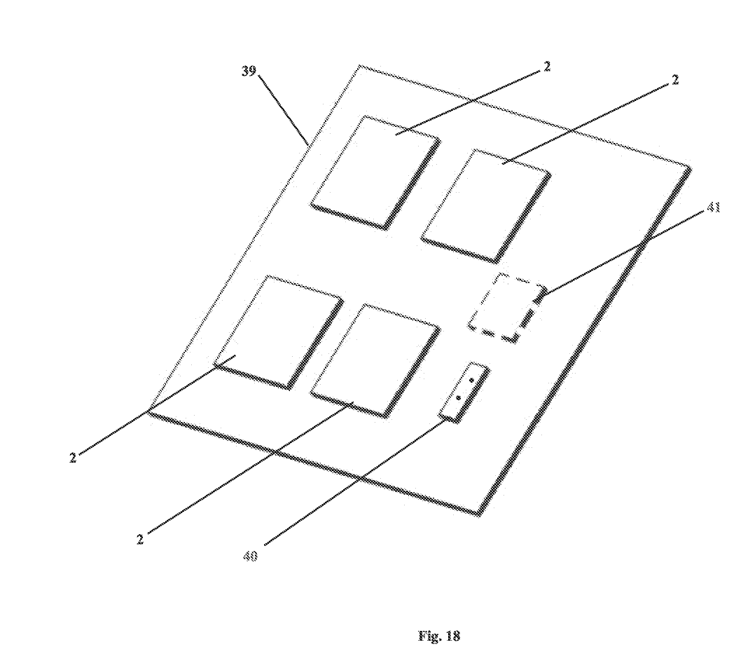

In yet another embodiment as shown in FIG. 7, the surface mounted solid state energy cells shown as (3c), (3d), (3e), and (3f) are attached to the rigid circuit board (10). Positive connection point (16a) of surface mounted solid state energy cell (3c) is attached to micro controller (11) end point (16n) using connection link (41). Negative connection point (16b) of surface mounted solid state energy cell (3c) is attached to micro controller (11) end point (16q) using connection link (4e).

Positive connection point (16c) of surface mounted solid state energy cell (3d) is attached to micro controller (11) end point (16n) using connection link (4f). Negative connection point (16d) of surface mounted solid state energy cell (3d) is attached to micro controller (11) end point (16j) using connection link (4g).

Positive connection point (16e) of surface mounted solid state energy cell (3e) is attached to micro controller (11) end point (16h) using connection link (4i). Negative connection point (16f) of surface mounted solid state energy cell (3e) is attached to micro controller (11) end point (16i) using connection link (4h).

Positive connection point (16s) of surface mounted solid state energy cell (3f) is attached to micro controller (11) end point (16o) using connection link (4k). Negative connection point (16r) of surface mounted solid state energy cell (3f) is attached to micro controller (11) end point (16p) using connection link (4j).

The micro controller (11) directs positive voltage to output connection point (16m) to connection link (14) and directs negative voltage to output connection point (16l) to connection link (13). Connection link (12) is used as needed. This embodiment of the apparatus is suitable for enclosure in a cell phone battery form factor casing.

Therefore, it is to be understood that within the scope of the appended claims the invention may be practiced other than as specifically described herein.

1. An energy storage module with a circuit board comprised of energy cells connected in series and enclosed in an appropriate casing to protect the circuit board
a biodegradable, non corrosive, non toxic coolant to help keep the energy cells cool as needed a control module that controls voltage output

2. An energy storage module with a circuit board or boards comprised of an energy cell

3. An energy storage module with a circuit board or boards comprised of an energy cell or cells appropriately connected in series or parallel

4. An energy storage module as described in claim 1, claim 2, and claim 3 wherein circuit board or boards are plugged into a receiving plug of appropriate configuration

5. An energy storage module as described in claim 1, wherein circuit boards are connected in parallel

6. An energy storage module as described in claim 1, wherein circuit boards are connected in series

7. An energy storage module as claimed in 1, claim 2, and claim 3, wherein voltage from the circuit board or boards is appropriately channeled to negative end plate

8. An energy storage module as claimed in 1, claim 2, and claim 3, wherein voltage from the circuit board or boards is appropriately channeled to positive end plate

9. An energy storage module as claimed in 1, claim 2, and claim 3, wherein output voltage is controlled by a control module

10. An energy storage module as claimed in 1, claim 2, and claim 3, wherein interior portion of casing for module or modules is protected with a anti corrosive material
